(19) United States
(12) Patent Application Publication
(10) Pub. No.: US 2005/0116141 A1
(43) Pub. Date: Jun. 2, 2005

(54) Method, assemblage, and scanner for optically sampling light by a photosensitive device

(76) Inventor: Roydan Thomas Tomlinson, Loveland, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/727,013

(22) Filed: Dec. 2, 2003

(51) Int. Cl. H01L 27/00

(52) U.S. Cl. 250/208.1

(57) ABSTRACT

An assemblage for sampling an image comprising a photosensitive element operable to convert light into an electrical charge, and a mask having a plurality of mask cells, each mask cell having an optically-conductive state and an optically-blocking state, a mask cell in an optically-conductive state permitting light to pass through to the photosensitive element.

### TECHNICAL FIELD

This invention relates to imaging technologies and, more particularly, to a method, assemblage, and scanner for optically sampling light by a photosensitive device.

### BACKGROUND

Image scanners convert a visible image on a document, photograph, or other medium into an electronic form suitable for copying, storing, or processing by a computer. Reflective image scanners typically have an illumination source that directs light onto a document surface to be imaged. Light is reflected from the document surface, through an optics system, and onto an array of photosensitive devices. The photosensitive devices convert received light intensity into an electronic signal. Transparency image scanners pass light through a transparent image, such as a photographic positive slide, through an optics system, and onto an array of photosensitive devices. A photosensitive device, such as a charge-coupled device (CCD), used in a scanner is frequently implemented as an array of photosensitive elements. The photosensitive device may comprise a one- or two-dimensional array of photosensitive elements.

The smallest area of a document image that is sampled by an individual element of a photosensitive device is referred to as a pixel. A pixel also refers to a set of numbers in a data set that electrically defines the image pixel. For example, a common specification of reflective and transparent image scanners is “pixels-per-inch” as measured on the surface of the document being scanned. Photosensor arrays employ numerous individual photosensitive elements (or alternatively sets of photosensitive elements when implemented in a color scanner) that respectively measure light intensity from a single area of the document, each element thereby defining one pixel on the document being scanned. The optical sampling rate, or resolution, is the number of samples optically captured from one scan line divided by the length of the scan line.

For black-and-white and grayscale scanners, there is a one-to-one correspondence between one pixel on the document being scanned, one sensor element, and one numerical intensity measurement. For color scanners, at least three sensor elements are employed to sense all the colors for one pixel on the document image and three corresponding numerical intensity values are used to represent all colors for one pixel on the document image.

Two general types of photosensor arrays are employed in image scanners: contact image sensors (CIS) arrays and charge-coupled device arrays. CIS arrays have a length equivalent to the length of the scan line. The primary advantage of CIS arrays is that reduction optics are not required. CCD arrays typically have a length that is smaller than the length of a scan line. Reduction optics are used to focus a scan line of the image onto the CCD array.

It is desirable to increase the resolution of a scanned image to provide sharper images. However, increasing the resolution of a photosensor array, whether a CIS array or CCD array, requires more pixels per scan line and, therefor, more photosensor elements per scan line. Increasing the number of photosensor elements results in a larger photosensor array. One approach to reducing the photosensor array size is to reduce the size of individual photosensor elements. However, each photosensitive element receives light from a fixed pixel area on the image being scanned. Thus, the minimum size of a photosensitive element is determined by integration circuit fabrication technology of the optics system, e.g., fundamental diffraction limits. Therefore, the photosensor array size increases in proportion to an increase in resolution.

### SUMMARY OF THE INVENTION

In accordance with an embodiment of the present invention, a method comprises directing light from an image onto a mask, switching a first area of the mask to an optically-conductive state, switching a remaining area of the mask to an optically-blocking state, sampling light passing through the first area of the mask by the photosensitive element, switching the first area to an optically-blocking state, switching the remaining area to an optically-conductive state, and sampling light passing through the remaining area by the photosensitive element.

In accordance with another embodiment of the present invention, an assemblage for sampling an image comprises a photosensitive element operable to convert light into an electrical signal, and a mask having a plurality of mask cells, each mask cell having an optically-conductive state and an optically-blocking state, a mask cell in an optically-conductive state permitting light to pass through to the photosensitive element.

In accordance with yet another embodiment of the present invention, an imaging device comprises a plurality of photosensitive elements arranged in a linear array, and a plurality of mask elements, each of the mask elements respectively associated with one of the plurality of photosensitive elements. Each mask element comprises a plurality of mask cells electrically switchable between optically-conductive and optically-blocking states.

### BRIEF DESCRIPTION OF THE DRAWINGS

For a more complete understanding of the present invention, the objects and advantages thereof, reference is now made to the following descriptions taken in connection with the accompanying drawings in which:

FIG. 1 is a schematic of a reduction optic device and photosensor array according to embodiments of the present invention;

FIG. 2 is a detailed schematic of a section of reduction optic device and photosensor array in the configuration illustrated in FIG. 1;

FIG. 3 is a schematic of an individual pixel and a photosensitive element sampling the pixel;

FIG. 4 is schematic of a pixel divided into portions that are sampled by a single photosensitive element according to an embodiment of the present invention;

FIGS. 5A-5D are respective schematics of mask cells in various optically-conductive states according to an embodiment of the present invention;

FIG. 6 is a schematic of a photosensitive array having photosensitive elements and associated mask cells in a configuration for sampling a scan line; and

FIG. 7 is a schematic of a mask cell implemented as a pockel cell according to an embodiment of the present invention.

### DETAILED DESCRIPTION OF THE DRAWINGS

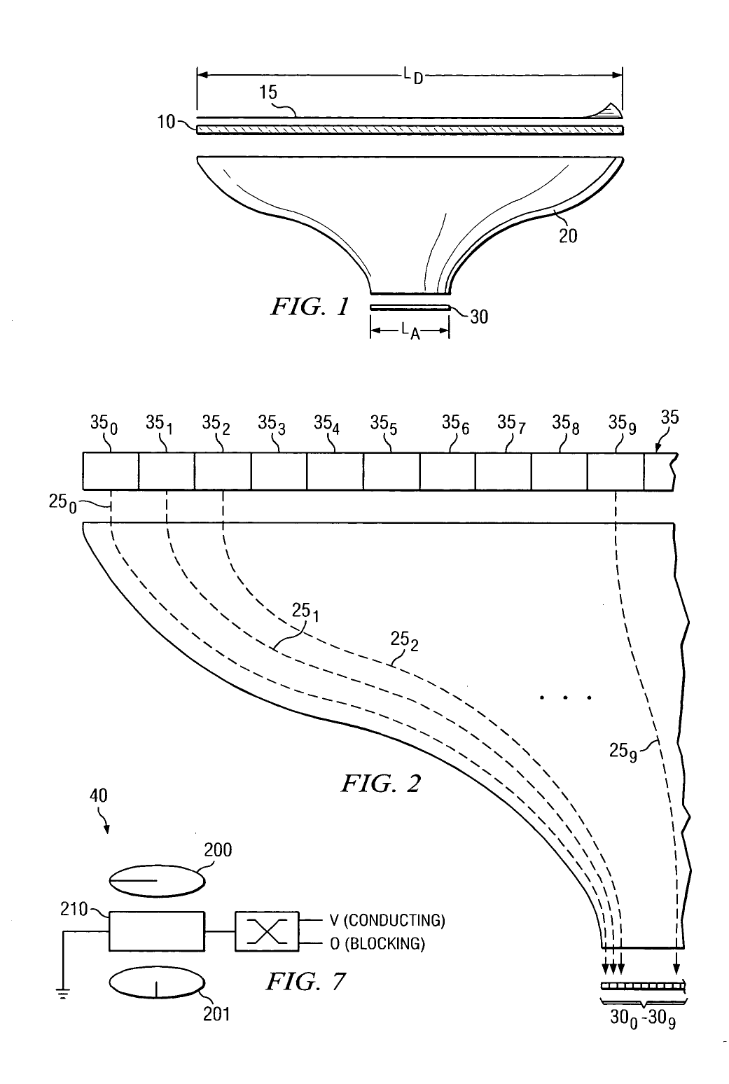

The preferred embodiment of the present invention and its advantages are best understood by referring to FIGS. 1 through 7 of the drawings, like numerals being used for like and corresponding parts of the various drawings.

FIG. 1 is a schematic of a reduction optic device 20 and photosensor array 30 according to embodiments of the present invention. A document 15 having an image to be scanned rests against a transparent platen 10. A scan line of document 15 is illuminated with a light source and light reflected from (or alternatively passed through) document 15 is directed into an optic device 20. Optic device 20 guides light reflected from document 15 onto a photosensor array 30. The length of document 15 (L_{D}) (and thus the scan line length) is generally greater than the length of photosensor array 30 (L_{A}). Optic device 20 facilitates reduction of the scan line length and is thus referred to as a reduction optic device.

FIG. 2 is a more detailed schematic of a section of reduction optic device 20 and photosensor array 30 in the configuration illustrated in FIG. 1. A portion of a scan line 35 of document 15 comprises pixels 350-359, or image areas, that are individually sampled by respective photosensitive elements 300-309. As light 250-259 is reflected from or through respective pixels 350-359 of document 15, optic device 20 guides light 250-259 onto element 300-309 of photosensor array 30. Elements 300-309 perform analog-to-digital conversion of the detected light intensity and respective data sets are generated that numerically define pixels 350-359.

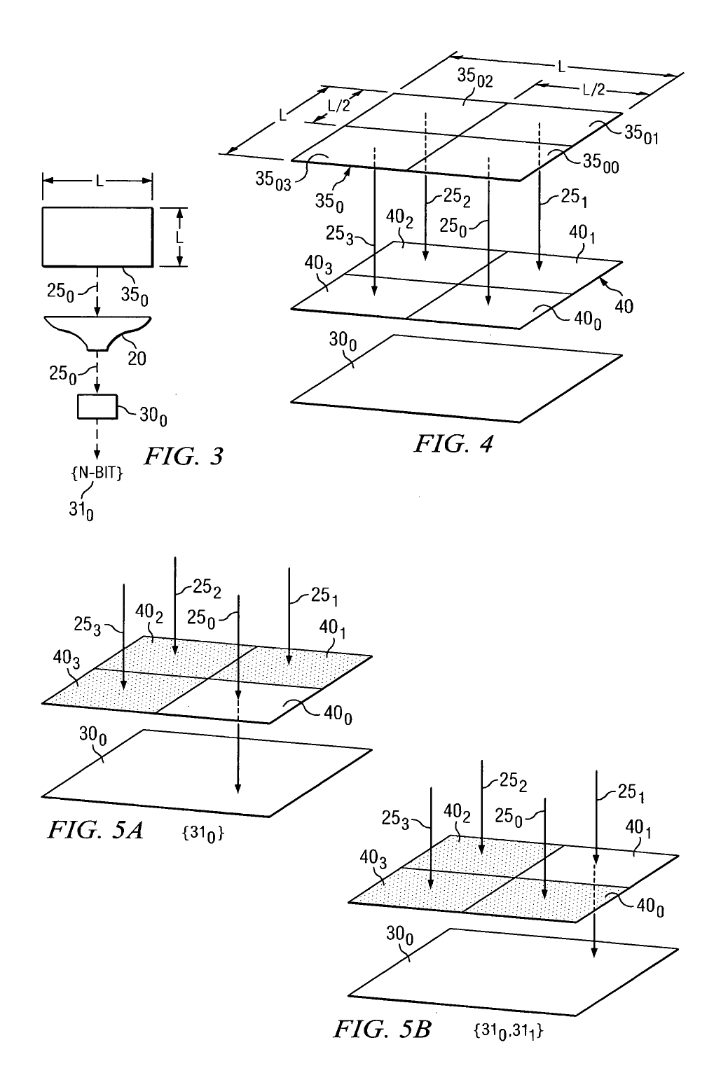

FIG. 3 is a schematic of an individual pixel 350 and photosensitive element 300 for sampling pixel 35₀. Optic device 20 functions to direct light from pixel 35₀ to photosensor array element 30₀. With reference also to FIG. 4, pixel 35₀ is illustratively divided into portions, e.g., quadrants 35₀₁-35₀₃, by using a mask 40. A single photosensitive element 30₀ is used to receive the reflected light from divided portions of pixel 35₀. The illustrative pixel 35₀ has length, L, and width, W. In the example shown in FIG. 4, L is equal to W and each quadrant 35₀₀-35₀₃ has length and width dimensions of L/2. Mask 40 comprises a plurality of mask cells 40₀-40₃. In the illustrative example, each mask cell 40₀-40₃ respectively corresponds to quadrant 35₀₀-35₀₃. Embodiments of the present invention are not, however, limited to a particular number or configuration of mask cells 40₀-40₃ and the mask cells may be arranged in an array or a matrix configuration. Furthermore, each mask may comprise an M×N matrix of cells, where M and N are integers. Preferably, mask cells 40₀-40₃ are implemented as electronically controlled light switches having two operational states: optically-conductive and optically-blocking.

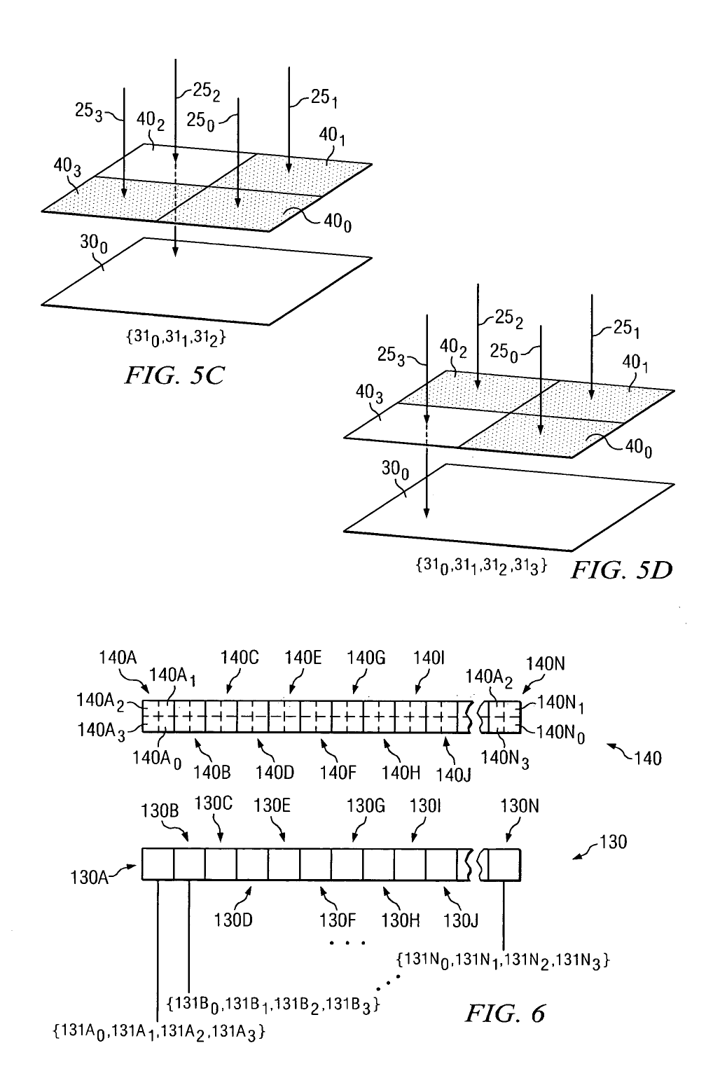

FIGS. 5A-5D are schematics of mask 40 illustrating operational states of mask cells 400-403 according to an embodiment of the present invention. For illustrative purposes, a mask cell state of optically-blocking is shown with appropriate shading. In FIG. 5A, mask cell 400 is optically-conductive and the remaining mask cells 401-403 are in a state of optically-blocking. In some embodiments, no more than a single mask cell is in an optically-conductive state at any given time. Turning to FIG. 5B, mask cell 400 is switched off and mask cell 401 is switched on (or placed in an optically-conductive state). Likewise, as shown in FIGS. 5C and 5D, mask cells 402 and 403 are alternatively switched on while respective mask cells 400, 401, and 403 and 400-402 are switched off, respectively.

In one embodiment, mask 40 is implemented by an array of electro-optic modulators such as pockel cell modulators. FIG. 7 is an exemplary mask cell 40₀ implemented as a pockel cell modulator in accordance with an embodiment of the invention. Pockel cell modulator 400 comprises two polarizers 200 and 201 having a crystal 210 disposed therebetween. Crystal 210 has optical properties that are modifiable by the application of an electric field. Particularly, the refraction properties of crystal 210 are changed upon application of a suitable electric field across crystal 210. Polarizers 200 and 201 are aligned at 90 degree offsets with respect to the polarization angles of polarizer 200 and 201 applied. During application of an electric field across crystal 210, crystal 210 is birefringent and, accordingly, light passes through crystal 210 and polarizer 201 prior to incidence on the photosensitive element. Alternatively, when an electric field is not applied across crystal 210, crystal 210 is not birefringent and the passage of light is prevented. Thus, an optically-conductive state of mask cell 40₀ is provided by an application of an electric field to crystal 210, and an optically-blocking state of mask cell 40₀ is provided by the absence of an electric field across crystal 210. Accordingly, mask 40 may be implemented as a 2-by-2 configuration of pockel cell modulators in an embodiment of the invention. Mask 40 is configured to sequentially cycle individual cells in an optically-conductive state by supplying an electric field across the crystal of a single pockel cell modulator while no electric field is supplied across the remaining pockel cell crystals.

Referring to FIG. 6, a photosensitive device 130 comprises a plurality of photosensitive elements 130A-130N arranged in a one-dimensional or two-dimensional array. In a preferred embodiment, each photosensitive element 130A-130N has an associated mask 140A-140N comprised of a plurality of mask cells 140A₀-140A₃-140N₀-140N₃ (illustratively denoted with dashed lines). The number, X, of photosensor elements 130A-130N and associated mask elements 140A-140N (each with Y mask cells) is arbitrary and photosensitive devices, such as CCD arrays, often comprise thousands of individual photosensitive elements.

Mask 140 is configured with photosensitive device 130 such that a single mask cell of each mask element 140A-140N is placed in an optically-conductive state and is optically coupled with a respective photosensitive element 130A-130N at a given time during the sampling of a scan line. Preferably, individual cells 140A₀-140A₃-140N₀-140N₃ are cycled through a single optically-conductive state and are placed in an optically-blocking state for the remainder of a scan line sampling process. For example, mask cells 140A₀-140N₀ are preferably placed in an optically-conductive state while the remaining mask cells 140A₁-140A₃-140N₁-140N₃ are placed in an optically-blocking state. During the sample period in which cells 140A₀-140N₀ are optically-conductive, photosensitive elements 130A-130N generate a respective data set 131A₀-131N₀ representative of the light intensity passing through cells 140A₀-140N₀. After passage of a sample period sufficient for photosensitive elements 130A-130N to generate respective samples, the optically-conductive cells 140A₀-140N₀ are switched to an optically-blocking state and another cell 140A₁-140N₁ of masks 140A-140N are switched to an optically-conductive state. Photosensitive elements 130A-130N generate respective data sets 131A₁-131N₁ after passage of light through cells 140A₁-140N₁ for the sample period. This process is repeated until photosensitive elements 130A-130N have sampled light passing through each of the remaining mask cells 140A2-140N2 and 140A3-140N3 and generated respective data sets 131A2-131N2 and 131A3-131N3 representative thereof.

The sampling of a scan line is completed after each of mask cells 140A0-140A3-140N0-140N3 have been cycled through an optically-conductive state. The sample data set comprises X·Y samples, where X is the number of photosensitive elements in the scan array and Y is the number of mask cells in each mask element. Accordingly, a minimum scan line sample period is equivalent to the product of the sample period of the photosensitive elements 130A-130N, Ts, and the number of mask cells in individual mask elements 140A-140N. In the particular configuration of the illustrative example, a scan line sample period is equal to 4Ts. It should be understood that each photosensitive element and mask may be further subdivided to achieve even greater resolution, for example a 4×4 matrix of cells sub-divided from a single mask for a single photosensitive element.

The above-described embodiments have included preferred configurations of a mask and photosensitive element or assemblage that may be implemented in a charge-coupled device photosensor array. However, embodiments of the invention may be implemented in other photosensory devices as well. For example, an assemblage of a mask and photosensitive array may be implemented in a contact image sensory array in accordance with embodiments of the invention. Additionally, the assemblage of the mask and photosensitive array described hereinabove comprises a one-dimensional array of both photosensitive elements and mask elements. However, such a configuration is exemplary only and has been chosen to facilitate an understanding of embodiments of the invention. Embodiments of the invention include implementation in two-dimensional photosensitive arrays and corresponding two-dimensional arrays of masks.

Embodiments of the present invention may be used to increase the resolution of various imaging devices without increasing the number or density of photosensitive devices. Therefore, a high-resolution scanner may be implemented using low-resolution photosensitive devices.

1. A method comprising:
directing light from an image onto a mask;
switching a first area of the mask to an optically-conductive state;
switching a remaining area of the mask to an optically-blocking state;
sampling light passing through the first area of the mask by a photosensitive element;
switching the first area to an optically-blocking state;
switching the remaining area to an optically-conductive state; and
sampling light passing through the remaining area by the photosensitive element.

2. The method according to claim 1, wherein switching the first area to an optically-conductive state further comprises switching the first area to an optically-conductive state for a sampling period of the photosensitive element.

3. The method according to claim 1, wherein switching the remaining area to an optically-conductive state comprises sequentially switching a plurality of areas in the remaining area of the mask to respective optically-blocking and optically-conductive states.

4. The method according to claim 1, wherein sampling light by the photosensitive element passing through the first area comprises sampling light by a charge-coupled device.

5. The method according to claim 1, wherein sampling light by the photosensitive element passing through the remaining area comprises sampling light by a charge-coupled device.

6. The method according to claim 1, wherein directing light onto a mask comprises directing light onto a pockel cell modulator.

7. The method according to claim 1, wherein sampling light passing through the first area comprises generating, by the photosensitive element, a data set representative of light intensity passed through the first area of the mask.

8. The method according to claim 1, wherein sampling light passing through the remaining area further comprises generating, by the photosensitive element, a data set representative of light intensity passed through the remaining areas of the mask.

9. An assemblage for sampling an image, comprising:
a photosensitive element operable to convert light into an electrical signal; and
a mask having a plurality of mask cells, each mask cell having an optically-conductive state and an optically-blocking state, a mask cell in an optically-conductive state permitting light to pass through to the photosensitive element.

10. The assemblage according to claim 9, wherein the plurality of mask cells in a mask are each sequentially switched to an optically-conductive state from an optically-blocking state.

11. The assemblage according to claim 10, wherein each of the plurality of mask cells are switched to an optically-conductive state for a pre-defined sample time period of the photosensitive element.

12. The assemblage according to claim 9, wherein the photosensitive element generates a plurality of samples of the image.

13. The assemblage according to claim 9, wherein the mask comprises an array of mask cells.

14. The assemblage according to claim 9, wherein the mask comprises a matrix of mask cells.

15. The assemblage according to claim 9, wherein the mask comprises a plurality of electrically switchable mask cells.

16. An imaging device comprising:
a plurality of photosensitive elements arranged in a linear array; and
a plurality of mask elements, each of the mask elements respectively associated with one of the plurality of photosensitive elements, and each mask element comprising a plurality of mask cells electrically switchable between optically-conductive and optically-blocking states.

17. The imaging device according to claim 16, wherein the mask elements are each configured to sequentially switch one of the plurality of mask cells to an optically-conducive state from an optically blocking state.

18. The imaging device according to claim 16, wherein the plurality of photosensitive elements generates X·Y samples, where X is the number of photosensitive elements and Y is the number of mask cells in each mask element.
